(19) United States
(12) Patent Application Publication
(10) Pub. No.: US 2009/0172504 A1
(43) Pub. Date: Jul. 2, 2009

(54) MEMORY ARCHITECTURE FOR VITERBI DECODER AND OPERATING METHOD THEREFOR

(75) Inventors: Yu-Chuan Huang, Taipei City (TW); Chun-Yuan Chu, Taipei City (TW); An-Yu Wu, Taipei City (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsin-Chu (TW)

(21) Appl. No.: 12/273,015

(22) Filed: Nov. 18, 2008

(30) Foreign Application Priority Data
Dec. 31, 2007 (TW) 096151390

(51) Int. Cl. H03M 13/05; G06F 11/10

(52) U.S. Cl. 714/795; 714/E11.032

(57) ABSTRACT

The Viterbi decoder is an essential module in a communication system, in which the power and the decoding latency are restricted. In the present invention, a power efficient low latency survivor memory architecture and an operating method for the Viterbi decoder are disclosed by providing a plurality of trace-forward units, a plurality of first signal selecting units, a plurality of second signal selecting units and a third signal selecting unit to reduce the power consumption by decreasing the exchange times of contents in the trace-forward units. Thus, the present invention is suitable for use in mobile communication devices which require low power consumption.

### BACKGROUND OF THE INVENTION

The present invention generally relates to a memory architecture for the Viterbi decoder and an operating method therefor and, more particularly, to a power efficient low latency survivor memory architecture for the Viterbi decoder and an operating method for the memory architecture.

The convolutional code has been widely used in communication systems to reduce transmission error. Among convolutional code decoding methods, the Viterbi algorithm is one with the maximum likelihood. More particularly, the survivor memory unit is the key part of the Viterbi decoder, upon which the decoding latency and the power consumption depend.

The Viterbi algorithm uses data matching to generate the survivor path for each state. As the data exceeds a certain amount, all the survivor paths converge to a correct solution. Meanwhile, the amount of data is referred to as a decoding length. The survivor memory unit (SMU) stores the survivor path to perform decoding after the decoding length is exceeded. Generally, the survivor memory architecture comprises two architectures as described hereinafter.

1. Register Exchange (RE) Architecture:

In a RE architecture, the registers are connected according to the trellis diagram of the convolutional encoder to perform data exchange according to the decision bits generated by an add-compare-select unit (ACSU). For detailed description, FIG. 1 shows a schematic diagram of a 4-state register exchange architecture, wherein multiplexers and D flip-flops are provided in each stage to perform data exchange between the registers ((i.e., D flip-flops) according to the decision bits d₀₀−d₁₁. As the number of connected stages reaches the decoding length, the registers of the last stage (i.e., the decision stage) store the converged decoded data to output a decoded symbol. In this architecture, the decoding latency is short because of trace-forward operation, but the power consumption is high since all the registers are performing data exchange.

FIG. 2 is a schematic diagram of 4-state decoding performed by trace-forward units. In a register exchange architecture, the registers store decoded data. After the decoding length, the registers of the last stage store converged decoded data. The operation of the trace-forward units is similar to that of the register exchange architecture except that the trace-forward units store the convergence state at some time instead of the decoded data. The content in the convergence state is the last data in the convergence state. Therefore, data decoding can be performed as long as the convergence state is obtained. In FIG. 2, there are two state bits and the decoding length is 8. These trace-forward units are initialized at time 0, 2, 4, 6. The state contents of all the registers in the trace-forward unit 0 converge to the same value, which is 2, at time 8, which means the converged state is state 2 at time 0 so that the decoded bits are {1_{t=-2, 0}ₜ₌₋₁}. The state contents of all the registers in the trace-forward unit 1 converge to the same value, which is 3, at time 10, which means the converged state is state 3 at time 2 so that the decoded bits are {1ₜ₌₀,1ₜ₌₁}. As the trace-forward units operate for a period of time until a decoding length is completed, the trace-forward units can be re-initialized for decoding operation in a next period of time. However, at steady state, all the registers in the aforesaid architecture are performing data exchange, which results in power consumption no less than the register exchange architecture.

2. Trace-Back (TB) Architecture:

FIG. 3 is a schematic diagram of a trace-back memory architecture, wherein four memory units are provided to store the decision bits generated by an ACSU until the decision bits are accumulated to complete a decoding length so that the a convergence state is obtained in a trace-back approach. Afterwards, decoding is performed in a trace-back approach. In such an architecture, the memory capacity is smaller, which results in lowered power consumption. However, the trace-back approach increases the decoding latency. Detailed description of FIG. 3 is provided as follows.

Write: Writing the decision bits into the memory unit in a time order;

Trace-Back: Reading the decision bits in a trace-back approach from a position where a last data is written so as to obtain a last convergence state;

Idle: The memory unit idle; and

Decode: reading survivor path information from the convergence state to perform decoding.

Since the wireless communication industry is continuously growing and the design of most transceivers is focused upon the reduction of power consumption, most of the Viterbi decoders used in transceivers use the trace-back approach for decoding. Therefore, there is need in providing a power efficient low latency survivor memory architecture for the Viterbi decoder and an operating method for the memory architecture to reduce power consumption of the Viterbi decoder by decreasing the exchange times of contents in the trace-forward units.

### SUMMARY OF THE INVENTION

One aspect of the invention to provide a memory architecture for the Viterbi decoder and an operating method thereof, being capable of reducing the power consumption and the decoding latency.

This aspect of the invention provides a memory architecture for the Viterbi decoder. The memory architecture has

a plurality of trace-forward units, capable of receiving a switching signal and a decision bit sequence respectively and generating a plurality of state signals according to the received decision bit sequence when the received switching signal is a turn-on signal; and a signal selecting unit, being electrically connected to the trace-forward units.

The signal selecting unit outputs a desired state bit sequence according to the state signals, a second decision signal, an initial state bit sequence and a last state bit sequence.

Another aspect of the invention further provides an operating method for a memory architecture for the Viterbi decoder. The operating method comprises:

(1) enabling each of a plurality of trace-forward units to receive a switching signal respectively, wherein one of the trace-forward units generates a plurality of state signals according to a received decision bit sequence when the switching signal is a turn-on signal, while the rest of the trace-forward units remain their original states;

(2) enabling a signal selecting unit to output a desired state bit sequence according to the state signals, a second decision signal, an initial state bit sequence and a last state bit sequence; and

(3) enabling the switching signal of a currently operating one of the trace-forward units to be a turn-off signal and enabling the switching signal of a next one of the trace-forward units to be a turn-on signal so as to go to step (1).

Thereby, the exchange times of contents in the trace-forward units are decreased to reduce the power consumption of the Viterbi decoder so that the problems in the conventional architecture and the operating method are overcome.

### BRIEF DESCRIPTION OF THE DRAWINGS

The objects, spirits and advantages of the embodiment of the present invention will be readily understood by the accompanying drawings and detailed descriptions, wherein:

FIG. 1 is a schematic diagram of a 4-state register exchange architecture;

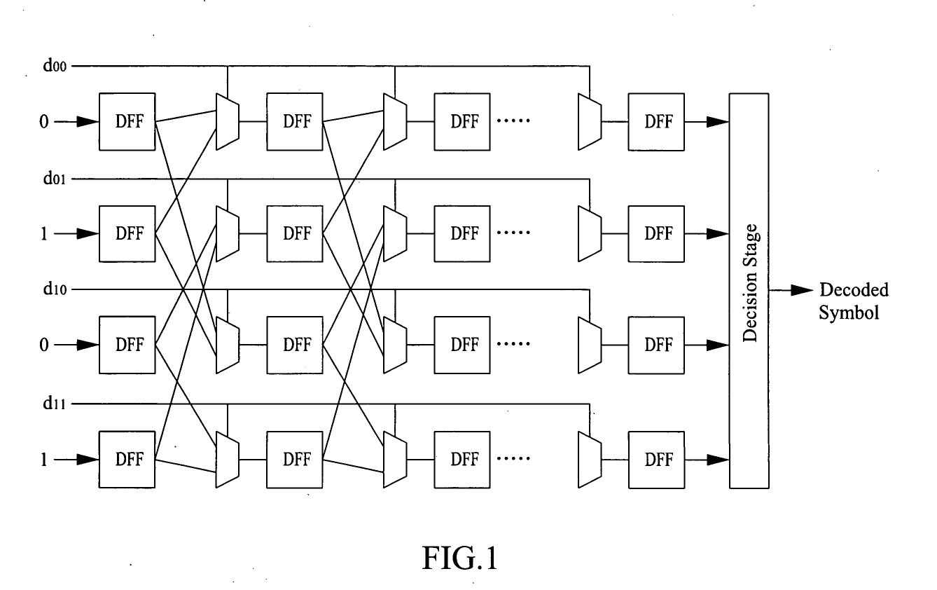

FIG. 2 is a schematic diagram of 4-state decoding performed by trace-forward units;

FIG. 3 is a schematic diagram of a trace-back memory architecture;

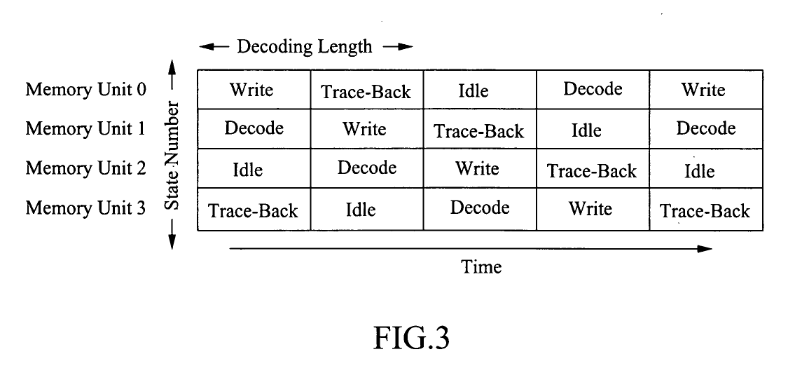

FIG. 4 is a circuit diagram of a memory architecture for the Viterbi decoder according to the embodiment of the present invention;

FIG. 5 is a flowchart of an operating method for a memory architecture for the Viterbi decoder according to the embodiment of the present invention; and

FIG. 6 is a schematic diagram of 4-state decoding performed by trace-forward units used in an operating method for a memory architecture for the Viterbi decoder according to the embodiment of the present invention.

### DETAILED DESCRIPTION OF THE EMBODIMENTS

The present invention can be exemplified but not limited by the embodiment as described hereinafter.

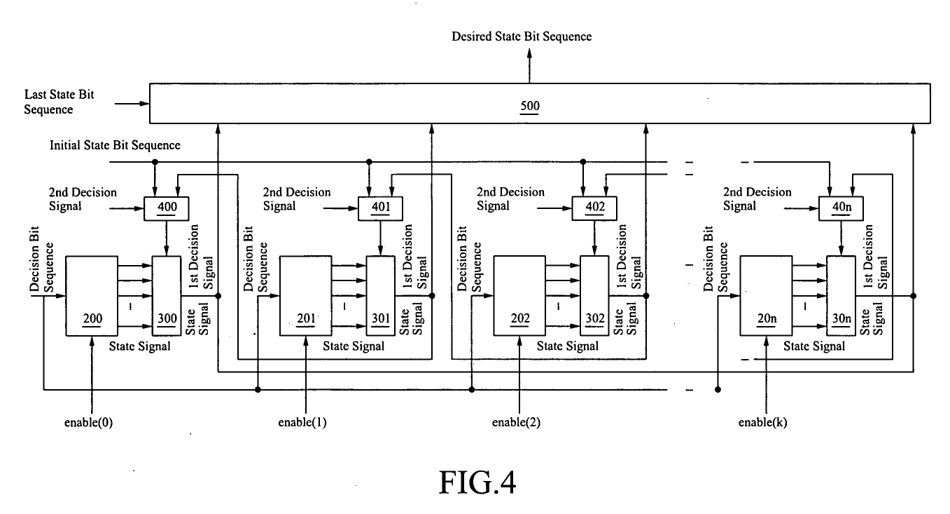

FIG. 4 is a circuit diagram of a memory architecture for the Viterbi decoder according to the embodiment of the present invention. In FIG. 4, the memory architecture for the Viterbi decoder 100 comprises: a plurality of trace-forward units 200-20n and a signal selecting unit.

The number of the trace-forward units 200-20n is not restricted. Each of the trace-forward units 200-20n receives a switching signal enable(1)-enable(k) and a decision bit sequence respectively, and generates a plurality of state signals according to the received decision bit sequence when the received switching signal is a turn-on signal. One of the switching signals is a turn-on signal while the rest of the switching signals are turn-off signals so that only one of the trace-forward units 200-20n is operating, which reduces the power consumption. The number of the bits in the decision bit sequence is not restricted.

The signal selecting unit comprising a plurality of first signal selecting units 300-30n, a plurality of second signal selecting units 400-40n and a third signal selecting unit 500. The first signal selecting units 300-30n are exemplified by and not restricted to multiplexers. The number of the first signal selecting units is not restricted. The first signal selecting units 300-30n are electrically connected to the trace-forward units 200-20n respectively. The first signal selecting units 300-30n receive the state signals respectively and select one from the state signals according to a first decision signal respectively.

The second signal selecting units 400-40n are exemplified by and not restricted to multiplexers. Similarly, the number of the second signal selecting units is not restricted. The second signal selecting units 400-40n are electrically connected to the first signal selecting units 300-30n respectively. The second signal selecting units 400-40n receive the initial state bit sequence and the state signals from the next first signal selecting units respectively, and select one from the state signals from the initial state bit sequence and the next first signal selecting units as the first decision signal output according to the second decision signal respectively. The number of bits in the initial state bit sequence is not restricted.

The third signal selecting unit 500 is exemplified by and not restricted to a multiplexer. The third signal selecting unit 500 is electrically connected to the first signal selecting units 300-30n. The third signal selecting unit 500 receives the state signals selected and output by the first signal selecting units 300-30n, and selects one from the state signals selected and output by the first signal selecting units 300-30n as the desired state bit sequence according to the last state bit sequence.

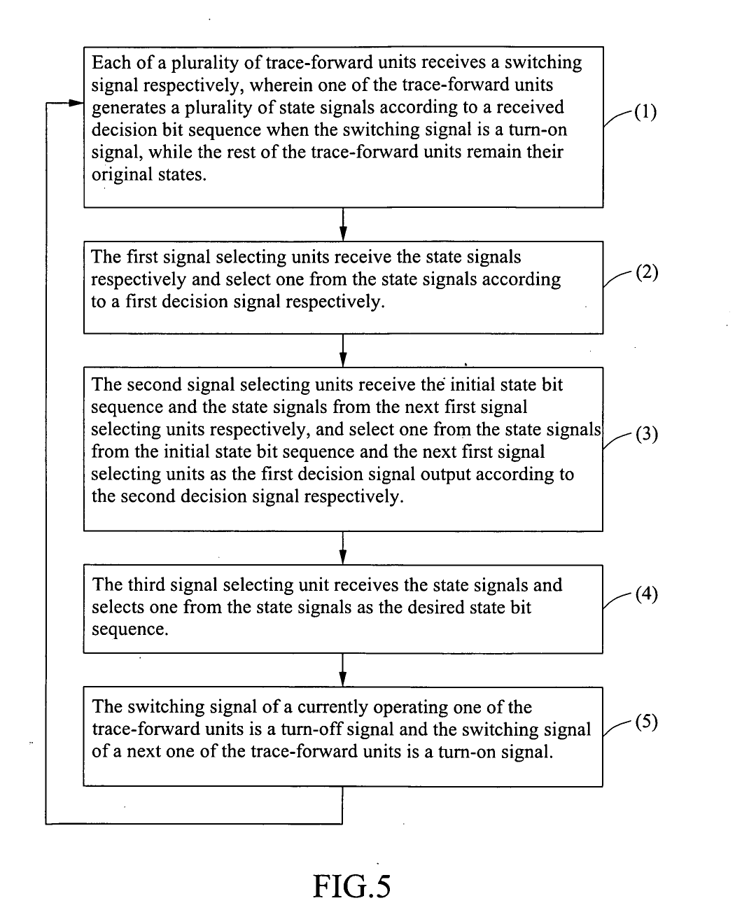

FIG. 5 is a flowchart of an operating method for a memory architecture for the Viterbi decoder according to the embodiment of the present invention. In the present invention, the memory architecture for the Viterbi decoder comprises a plurality of trace-forward units and a signal selecting unit. The signal selecting unit comprise a plurality of first signal selecting units, a plurality of second signal selecting units and a third signal selecting unit. The first signal selecting units are electrically connected to the trace-forward units respectively. The second signal selecting units are electrically connected to the first signal selecting units respectively. The third signal selecting unit is electrically connected to the first signal selecting units. The operating method comprises steps as described hereinafter:

In Step (1), each of a plurality of trace-forward units receives a switching signal respectively, wherein one of the trace-forward units generates a plurality of state signals according to a received decision bit sequence when the switching signal is a turn-on signal, while the rest of the trace-forward units remain their original states. One of the switching signals is a turn-on signal while the rest of the switching signals are turn-off signals so that only one of the trace-forward units is operating, which reduces the power consumption. The number of the trace-forward units is not restricted, and neither is the number of the bits in the decision bit sequence.

In Step (2), the first signal selecting units (exemplified by and not limited to multiplexers) receive the state signals respectively and select one from the state signals according to a first decision signal respectively. The number of the first signal selecting units is not restricted.

In Step (3), the second signal selecting units (exemplified by and not limited to multiplexers) receive the initial state bit sequence and the state signals from the next first signal selecting units respectively, and select one from the state signals from the initial state bit sequence and the next first signal selecting units as the first decision signal output according to the second decision signal respectively. The number of the second signal selecting units is not restricted, and neither is the number of the bits in the initial state bit sequence.

In Step (4), the third signal selecting unit (exemplified by and not limited to a multiplexer) receives the state signals selected and output by the first signal selecting units, and selects one from the state signals selected and output by the first signal selecting units as the desired state bit sequence according to the last state bit sequence.

In Step (5), the switching signal of a currently operating one of the trace-forward units is a turn-off signal and the switching signal of a next one of the trace-forward units is a turn-on signal so as to go to step (1).

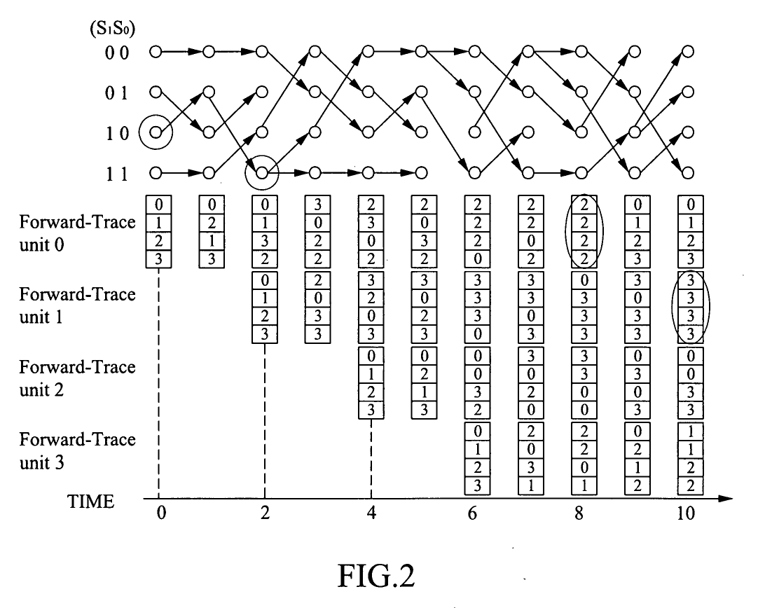

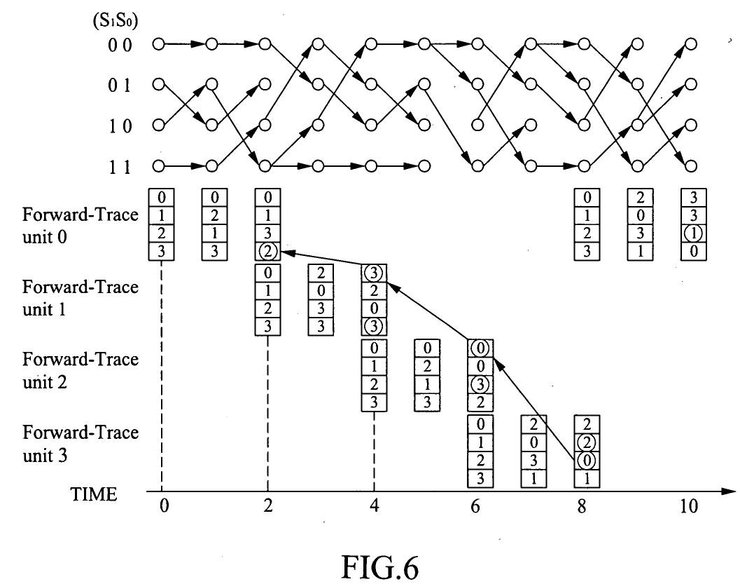

FIG. 6 is a schematic diagram of 4-state decoding performed by trace-forward units used in an operating method for a memory architecture for the Viterbi decoder according to the embodiment of the present invention. In FIG. 6, each of the trace-forward units only operates twice and then a next trace-forward unit starts to operate. As the decision bits are accumulated to complete a decoding length, the survivor memory unit traces back from the last trace-forward unit. Similar to FIG. 2, since the survivor paths are connected, a convergence state can be obtained in the trace-back approach. Obviously, in the present invention, only one trace-forward unit is operating at any time, which reduces the power consumption.

Accordingly, the present invention discloses a memory architecture for the Viterbi decoder and an operating method for the memory architecture to reduce power consumption of the Viterbi decoder by decreasing the exchange times of contents in the trace-forward units. Therefore, the present invention is useful, novel and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A memory architecture for the Viterbi decoder, comprising:
a plurality of trace-forward units, each being capable of receiving a switching signal and a decision bit sequence respectively and generating a plurality of state signals according to the received decision bit sequence when the received switching signal is a turn-on signal; and
a signal selecting unit, being electrically connected to the trace-forward units;
wherein the signal selecting unit outputs a desired state bit sequence according to the state signals, a second decision signal, an initial state bit sequence and a last state bit sequence.

2. The memory architecture for the Viterbi decoder as recited in claim 1, wherein the signal selecting unit comprises a plurality of first signal selecting units, a plurality of second signal selecting units and a third signal selecting unit, wherein the trace-forward units are electrically connected to the first signal selecting units respectively, the first signal selecting units are electrically connected to the second signal selecting units, the second signal selecting units are electrically connected to the third signal selecting unit, and the third signal selecting unit outputs the desired state bit sequence according to the last state bit sequence.

3. The memory architecture for the Viterbi decoder as recited in claim 2, wherein:
the first signal selecting units are electrically connected to the trace-forward units respectively, receive the state signals respectively and select one from the state signals according to a first decision signal respectively;
the second signal selecting units receive the initial state bit sequence and the state signals from the next first signal selecting units respectively, and select one from the state signals from the initial state bit sequence and the next first signal selecting units as the first decision signal output according to the second decision signal respectively; and
the third signal selecting unit receives the state signals selected and output by the first signal selecting units, and selects one from the state signals selected and output by the first signal selecting units as the desired state bit sequence according to the last state bit sequence.

4. The memory architecture for the Viterbi decoder as recited in claim 2,
wherein the first signal selecting units are multiplexers.

5. The memory architecture for the Viterbi decoder as recited in claim 2,
wherein the second signal selecting units are multiplexers.

6. The memory architecture for the Viterbi decoder as recited in claim 2,
wherein the third signal selecting unit is a multiplexer.

7. The memory architecture for the Viterbi decoder as recited in claim 1,
wherein one of the switching signals is a turn-on signal while the rest of the switching signals are turn-off signals.

8. An operating method for a memory architecture for the Viterbi decoder, comprising:
(1) enabling each of a plurality of trace-forward units to receive a switching signal respectively, wherein one of the trace-forward units generates a plurality of state signals according to a received decision bit sequence when the switching signal is a turn-on signal, while the rest of the trace-forward units remain their original states;
(2) enabling a signal selecting unit to output a desired state bit sequence according to the state signals, a second decision signal, an initial state bit sequence and a last state bit sequence; and
(3) enabling the switching signal of a currently operating one of the trace-forward units to be a turn-off signal and enabling the switching signal of a next one of the trace-forward units to be a turn-on signal so as to go to step (1).

9. The operating method as recited in claim 8, wherein the signal selecting unit comprises:
a plurality of first signal selecting units, being electrically connected to the trace-forward units respectively;
a plurality of second signal selecting units, being electrically connected to the first signal selecting units respectively; and
a third signal selecting unit, being electrically connected to the first signal selecting units respectively.

10. The operating method as recited in claim 9, wherein the step (2) further comprises steps of:
(21) enabling the first signal selecting units to receive the state signals respectively and to select one from the state signals according to a first decision signal respectively;
(22) enabling the second signal selecting units to receive the initial state bit sequence and the state signals from the next first signal selecting units respectively and to select one from the state signals from the initial state bit sequence and the next first signal selecting units as the first decision signal output according to the second decision signal respectively; and
(23) enabling the third signal selecting unit to receive the state signals selected and output by the first signal selecting units, and to select one from the state signals selected and output by the first signal selecting units as the desired state bit sequence according to the last state bit sequence.

11. The operating method as recited in claim 9, wherein the first signal selecting units are multiplexers.

12. The operating method as recited in claim 9, wherein the second signal selecting units are multiplexers.

13. The operating method as recited in claim 9, wherein the third signal selecting unit is a multiplexer.

14. The operating method as recited in claim 8, wherein one of the switching signals is a turn-on signal while the rest of the switching signals are turn-off signals.
